(19) United States
(12) Patent Application Publication
(10) Pub. No.: US 2026/0072098 A1
(43) Pub. Date: Mar. 12, 2026

(54) ARRANGEMENT AND METHOD FOR TESTING AN INVERTER AND/OR A CONVERTER

(71) Applicant: dSPACE GmbH, Paderborn (DE)

(72) Inventor: Daniel Epping, Paderborn (DE)

(21) Appl. No.: 19/321,323

(22) Filed: Sep. 8, 2025

(30) Foreign Application Priority Data
Sep. 9, 2024 (DE) 102024125732.6

(51) Int. Cl. G01R 31/42; G01R 31/3183

(52) U.S. Cl. CPC G01R 31/42; G01R 31/318314

(57) ABSTRACT

A system for testing an inverter and/or a converter includes: a first emulation device configured to emulate a power generator; a second emulation device configured to emulate a power consumer; and a control device. The first emulation device comprises at least one first current-optimized load module. The second emulation device comprises at least one parallel circuit composed of a second dynamics-optimized load module and a second current-optimized load module. The first current-optimized load module and the second current-optimized load module each comprise an at least two-stage inverter. The second dynamics-optimized load module comprises an at least three-stage inverter. The control device is configured to: control the second current-optimized load module based on a low-pass-filtered output voltage of the inverter and/or the converter; and control the second dynamics-optimized load module based on a high-pass-filtered output voltage of the inverter and/or the converter.

### CROSS-REFERENCE TO PRIOR APPLICATIONS

This application claims benefit to German Patent Application No. DE 102024125732.6, filed on Sep. 9, 2024, which is hereby incorporated by reference herein.

### FIELD

The invention relates to an arrangement for testing an inverter and/or a converter, comprising a first emulation device which is configured to emulate a power generator, a second emulation device which is configured to emulate a power consumer, the inverter and/or converter which is connected between the first emulation device and the second emulation device and has a DC link capacitor connected in parallel, and a control device.

The invention furthermore relates to a method for testing an inverter and/or a converter, comprising a first emulation device which is configured to emulate an energy generator, a second emulation device which is configured to emulate an energy consumer, the inverter and/or converter which is connected between the first emulation device and the second emulation device and has a DC link capacitor connected in parallel.

### BACKGROUND

Electric motors in variable-speed drives are usually operated via switching power electronics. The aim of such power electronics is to impress the most sinusoidal possible current of variable fundamental frequency into the electric motor. A resulting torque causes the electric motor to rotate at the same electrical rotational frequency ω.

Since modern power electronics having subordinate pulse width modulation operate at a particular switching frequency fs of, for example, 10 kHz, a desired sinusoidal motor current fundamental wave at the electrical rotational frequency ω is superimposed by a high-frequency triangular switching ripple with a period duration of 1/fs.

In order to depict a behavior of an actual electric motor on switching power electronics in a manner true to reality with the aid of electronic loads in a power hardware-in-the-loop (HIL) environment, that is to say in a hardware-in-the-loop simulator at power level, the motor current fundamental wave including the resulting current ripple must be reproduced at the switching frequency of the power electronics fs, wherein the aim is motor current fundamental waves up to a maximum of 5 kHz.

In conventional applications, fast-switching current-controlled multilevel converters are used as current sources for this purpose. Such inverters are also referred to as load modules. Known load modules are optimized for maximum dynamics, that is to say for reproduction of motor current ripples in the range of from 10 to 100 kHz, like those resulting from the operation of an electric motor at a clocking output stage.

However, the requirements for a maximally high bandwidth with simultaneously high current control accuracy require complex power electronics hardware structures. An effective switching frequency f_{sLoadModule} of a load module for a target application of up to several 1000 A rated current in the MW range is therefore approximately 800 kHz. The switching frequency f_{sLoadModule} refers to the frequency at which the load module can apply a new voltage level at the output in order to control the desired setpoint current.

However, high switching losses occur due to the high switching frequency. The realizable current in relation to the volume of the installation space is low for such power electronics, but a cooling effort is relatively high. Corresponding hardware structures are usually complex and expensive. Due to a design of the load module for dynamics and accuracy, each load module is limited, for example, to a current of 75 A. If the desire is to equip known power HIL systems for the emulation of an electric machine of a wind power plant with a current of 1000 A, about 14 load modules per phase are required in order to be able to provide a required total current for the emulation of an electric machine, in particular the electric motor.

An analogous problem occurs when emulating electrical power supply systems in an equally high power range. Often, not only should a system fundamental wave be depicted, but also a system harmonic of a higher order n, which is superimposed on the system fundamental wave. The harmonic has an n-fold frequency of the system fundamental wave and an amplitude of 1/n of a fundamental wave amplitude.

Even when emulating a high-voltage DC on-board vehicle electrical system of an electric vehicle, on the one hand higher and higher currents must be covered and on the other hand highly dynamic reactions of switching power electronics of lower amplitude must be covered by the emulation.

### SUMMARY

In an exemplary embodiment, the present invention provides a system for testing an inverter and/or a converter. The system includes: a first emulation device configured to emulate a power generator; a second emulation device configured to emulate a power consumer; and a control device. The inverter and/or the converter is connected between the first emulation device and the second emulation device and has a direct current (DC) link capacitor connected in parallel. The first emulation device comprises at least one first current-optimized load module. The second emulation device comprises at least one parallel circuit composed of a second dynamics-optimized load module and a second current-optimized load module. The first current-optimized load module and the second current-optimized load module each comprise an at least two-stage inverter. The second dynamics-optimized load module comprises an at least three-stage inverter. The control device is configured to: control the second current-optimized load module based on a low-pass-filtered output voltage of the inverter and/or the converter; and control the second dynamics-optimized load module based on a high-pass-filtered output voltage of the inverter and/or the converter.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic arrangement for testing an inverter according to one preferred exemplary embodiment;

FIG. 2 shows a schematic arrangement for testing the inverter according to another preferred exemplary embodiment;

FIG. 3 shows a schematic arrangement for testing a converter according to yet another preferred exemplary embodiment;

FIG. 4 shows a schematic view of a dynamics-optimized load module of the arrangement according to FIGS. 1 to 3; and

FIG. 5 shows a schematic view of a current-optimized load module of the arrangement according to FIGS. 1 to 3.

### DETAILED DESCRIPTION

Exemplary embodiments of the present invention provide an arrangement, which is simplified in terms of circuitry, and a corresponding method, for testing an inverter and/or a converter that, compared to the prior art, enables a maximally high bandwidth at the same time as high current control accuracy with minimal complex power electronics hardware structures.

In an exemplary embodiment, the present invention provides a system for testing an inverter and/or a converter, comprising a first emulation device which is configured to emulate a power generator, a second emulation device which is configured to emulate a power consumer, the inverter and/or converter which is connected between the first emulation device and the second emulation device and has a DC link capacitor connected in parallel, and a control device, wherein

the first emulation device comprises at least one first current-optimized load module and the second emulation device comprises at least one parallel circuit composed of a second dynamics-optimized load module and a second current-optimized load module,
the first current-optimized load module and the second current-optimized load module each comprise an at least two-stage inverter, and the second dynamics-optimized load module comprises an at least three-stage inverter, and
the control device is configured to control the second current-optimized load module based on a low-pass-filtered output voltage of the inverter and/or the converter and to control the second dynamics-optimized load module based on a high-pass-filtered output voltage of the inverter and/or the converter.

Relative to conventional technology, in which, for example, about 14 load modules per phase were required to emulate an electric machine of a wind power plant with a current of 1000 A in order to provide a required total current for the emulation of an electric motor, exemplary embodiments of the present invention provide that the second dynamics-optimized load module and the second current-optimized load module are connected in parallel, wherein the second current-optimized load module is controlled based on the low-pass-filtered output voltage of the inverter and/or the converter and the second dynamics-optimized load module is controlled based on the high-pass-filtered output voltage of the inverter and/or the converter.

In other words, a motor current ripple, as is the case with the operation of a motor at a clocking output stage, in particular in the range of from 10 to 100 kHz and/or at an effective switching frequency of approximately 800 kHz, is depicted via a load module optimized for dynamics and to depict a motor current fundamental wave, in particular in the range of from 0 to 5 kHz, by a current-optimized load module with in particular a much lower bandwidth in comparison, namely in particular for a much higher nominal current in comparison. A system emulation and a battery emulation can be done in the same way. In summary, the provided arrangement enables a significant increase in a power density of a power HIL system while simultaneously reducing costs compared to conventional arrangements.

The first current-optimized load module and the second current-optimized load module are preferably physically designed in the same way and/or designed in particular for a high current and/or in a manner limited in terms of bandwidth. A first dynamics-optimized load module and the second dynamics-optimized load module are preferably physically designed in the same way and/or designed in particular for higher dynamics and accuracy compared to the respective current-optimized load module. Using such load modules that are less expensive to manufacture than dynamics-optimized load modules makes it possible to manufacture the arrangement less expensively. The control device is preferably designed as a microprocessor, as a programmable logic controller, as a computer device or similar.

According to one preferred development, the inverter and/or the converter are of three-phase design, the second emulation device comprises a respective parallel circuit composed of the second dynamics-optimized load module and the second current-optimized load module for each phase, and the control device is designed to control the second current-optimized load module of the respective phase based on the low-pass-filtered output voltage of the respective phase of the inverter and/or the converter and to control the second dynamics-optimized load module of the respective phase based on the high-pass-filtered output voltage of the respective phase of the inverter and/or the converter.

According to another preferred refinement, the arrangement comprises the inverter, wherein the control device is configured to control the first current-optimized load module based on an input current of the inverter. Such a refinement can be used to emulate a generator and a power supply grid having the inverter, for example a wind power plant in the MW range.

According to one preferred development, the first emulation device comprises at least one parallel circuit, in particular at least two parallel circuits, composed of a first current-optimized load module and the first dynamics-optimized load module and the control device is configured to control the first current-optimized load module based on a low-pass-filtered input current of the inverter and to control the first dynamics-optimized load module based on a high-pass-filtered input current of the inverter.

According to another preferred refinement, the arrangement comprises the converter, wherein the converter is of three-phase design, the first emulation device comprises a respective parallel circuit composed of a first dynamics-optimized load module and the first current-optimized load module for each phase, and the control device is designed to control the first current-optimized load module of the respective phase based on the low-pass-filtered input voltage of the respective phase of the converter and to control the first dynamics-optimized load module of the respective phase based on the high-pass-filtered input voltage of the respective phase of the converter.

According to one preferred development, the low-pass filtering is carried out at a cutoff frequency of ≤5 kHz, in particular ≤3 kHz, and the high-pass filtering is carried out at the cutoff frequency of ≥8 kHz, in particular ≥10 kHz. A cutoff frequency of the low-pass filtering or of a low-pass filter is preferably selected such that the motor current fundamental wave remains unaffected. The motor current fundamental wave is usually below 5 kHz. A cutoff frequency of the high-pass filtering or of a high-pass filter is preferably selected such that a resulting motor current ripple component remains unaffected. The cutoff frequency is typically 8 to 10 kHz.

According to another preferred refinement, a plurality of first current-optimized load modules connected in series and/or in parallel and/or second current-optimized load modules connected in series and/or in parallel are provided. By way of such a plurality, for example 2, 3, 4 or 5, of first current-optimized load modules and/or second current-optimized load modules connected in series and/or in parallel, it is possible to emulate even higher currents in a fairly simple and equally cost-effective manner.

According to one preferred development, the control device comprises an field programmable gate array (FPGA). The control device is preferably part of the first emulation device and/or the second emulation device. The first emulation device and the second emulation device can likewise be designed as a joint emulation device. The emulation device may be designed to accommodate breadboards, the functionality of which includes, for example, signal measurement, simulation of particular sensor signals, battery simulation, simulation of electrical faults such as short circuits or loose contacts, while other breadboards may be used as gateways for different bus standards or for the integration of FPGAs.

According to another preferred refinement, the first dynamics-optimized load module and the second dynamics-optimized load module each comprise an at least seven-stage inverter. A seven-stage inverter such as this can be used, for example, to cover a frequency range or a switching frequency of 800 kHz and simultaneously provide a current of up to 75 A.

According to one preferred development, the first emulation device comprises a battery and/or a generator and/or the second emulation device comprises a motor and/or a power supply system. The first emulation device is preferably designed as a battery and/or as a generator and/or the second emulation device is preferably designed as a motor and/or as a power supply system or as part of the power supply system and/or is connected thereto. The provided arrangement makes it possible to emulate the above-mentioned components, for example wind power plants in the MW range, in a simple and particularly cost-effective manner.

In an exemplary embodiment, the present invention further provides an arrangement for testing an inverter and/or a converter of a wind power plant, a power supply system and/or a battery, in particular an electric vehicle.

In an exemplary embodiment, the present invention further provides a method for testing an inverter and/or a converter, comprising a first emulation device which is configured to emulate an energy generator, a second emulation device which is configured to emulate an energy consumer, the inverter and/or converter which is connected between the first emulation device and the second emulation device and has a DC link capacitor connected in parallel, wherein

the first emulation device comprises at least one first current-optimized load module and the second emulation device comprises at least one parallel circuit composed of a second dynamics-optimized load module and a second current-optimized load module,
the first current-optimized load module and the second current-optimized load module each comprise an at least two-stage inverter, and the second dynamics-optimized load module comprises an at least three-stage inverter, and having the following steps:
controlling the second current-optimized load module based on a low-pass-filtered output voltage of the inverter and/or the converter, and
controlling the second dynamics-optimized load module based on a high-pass-filtered output voltage of the inverter and/or the converter.

Further refinements and advantages of the method will be appreciated in view of the foregoing description of the analogous system arrangement.

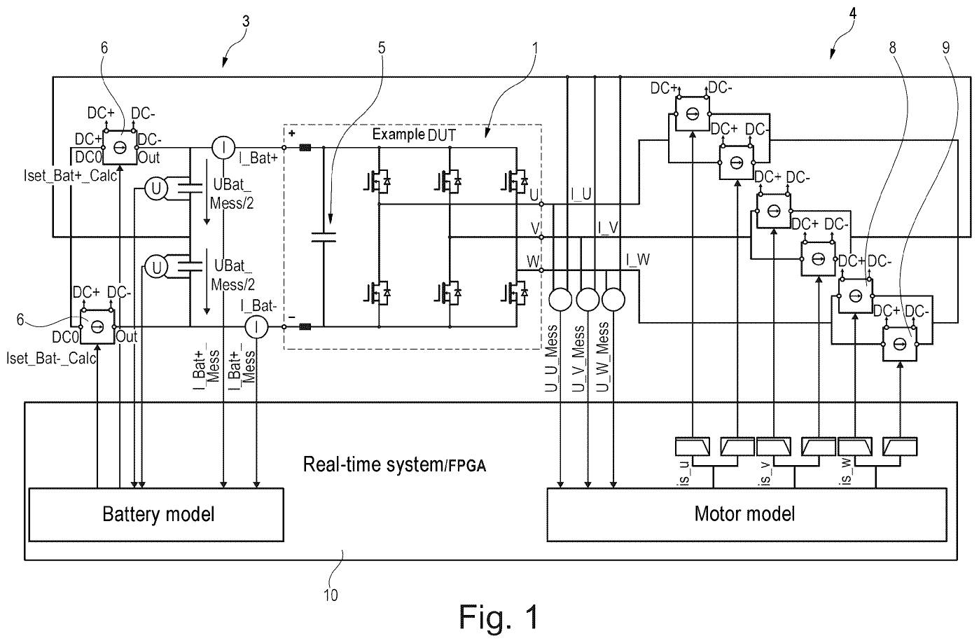

FIGS. 1 to 3 each show a schematic view of an arrangement for testing an inverter 1 and/or a converter 2 according to one preferred exemplary embodiment.

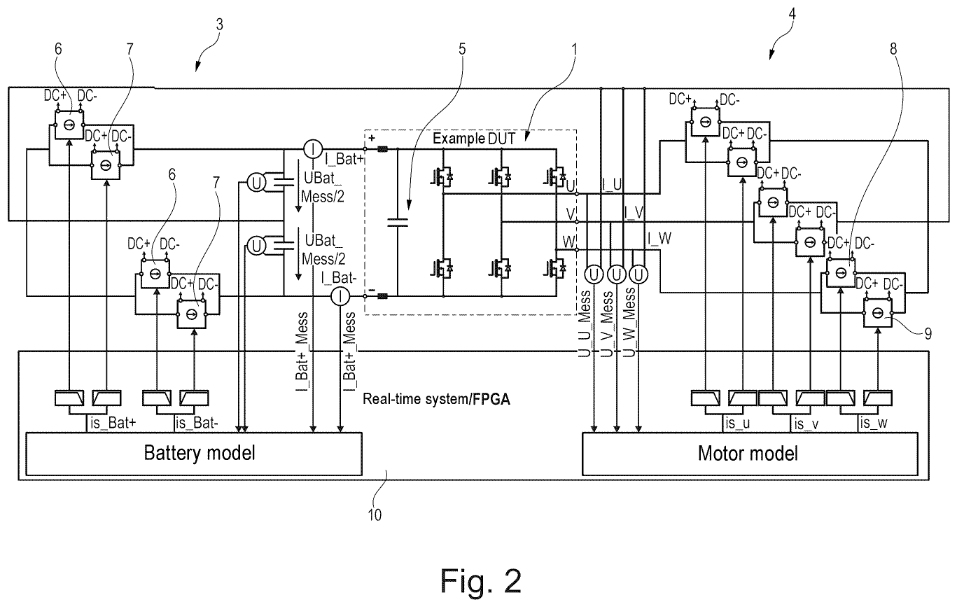

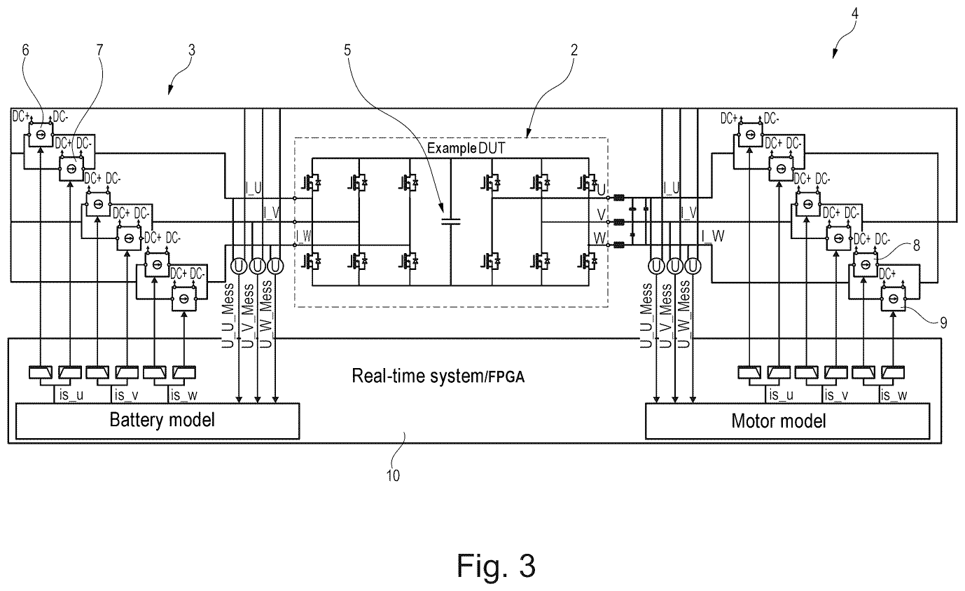

The respective arrangement comprises a first emulation device 3 for emulating a power generator and a second emulation device 4 which is configured to emulate a power consumer. The first emulation device 3 of FIGS. 1 and 2 represents a battery model, while the second emulation device 4 of FIGS. 1 and 2 represents a motor model. The first emulation device 3 of FIG. 3 represents a generator model, while the second emulation device 4 of FIG. 3 represents a system model.

In FIGS. 1 and 2, the inverter 1 is connected between the first emulation device 3 and the second emulation device 4, wherein a DC link capacitor 5 is connected in parallel with the inverter 1 on the input side. In FIG. 3, the converter 2 is connected between the first emulation device 3 and the second emulation device 4 and the DC link capacitor 5 is also connected in the voltage link in parallel with an output of a rectifier of the converter 2 and in parallel with an input of an inverter of the converter 2. As is known from the prior art, the inverter 1 and the converter 2 comprise insulated-gate bipolar transistors (IGBTs) having diodes connected in parallel, as can be seen in FIGS. 1 to 3.

The first emulation device 3 of the refinement shown in FIG. 1 comprises two first current-optimized load modules 6, the output sides of which are connected to an input of the inverter 1, that is to say they are each connected to a positive and a negative input of the inverter 1. In the embodiment shown in FIG. 2, the first emulation device 3 additionally comprises two first dynamics-optimized load modules 7, which are each connected in parallel with the two first current-optimized load modules 6. The refinement shown in FIG. 3 has a parallel circuit composed of a first current-optimized load module 6 and a first dynamics-optimized load module 7 for each phase. The second emulation device 4 of the refinements shown in FIGS. 1 to 3 has a parallel circuit composed of a second current-optimized load module 8 and a second dynamics-optimized load module 9 for each phase.

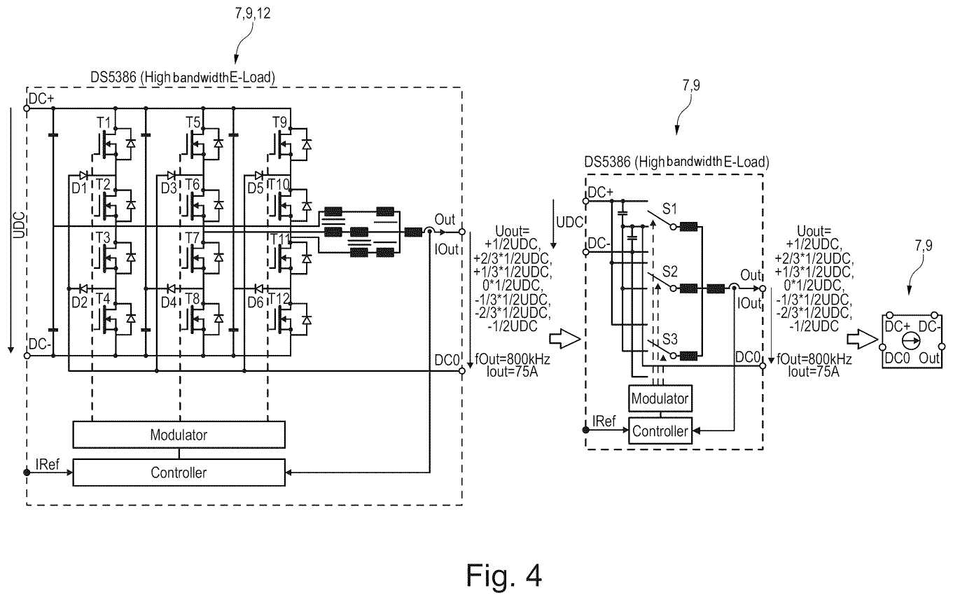

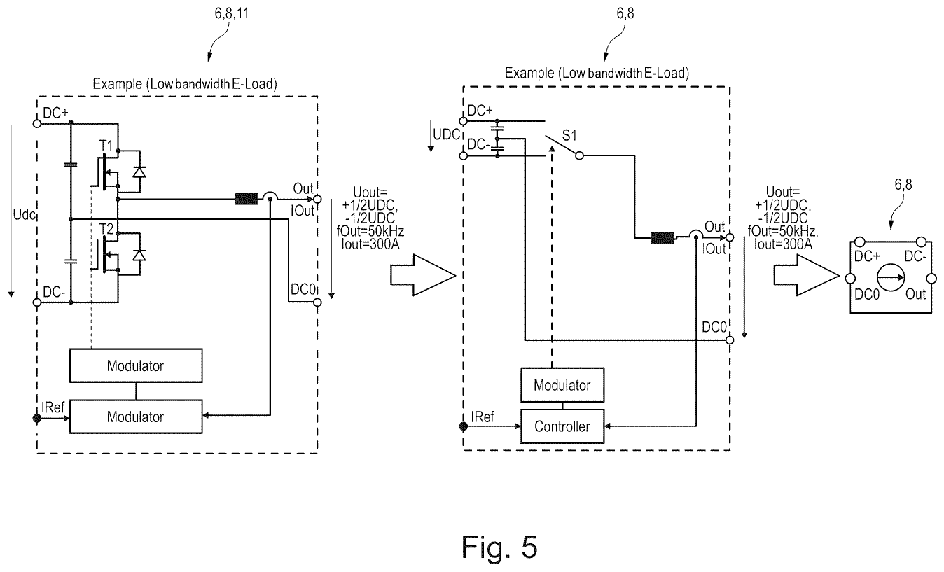

The first dynamics-optimized load modules 7 and the second dynamics-optimized load modules 9 are each physically designed in the same way and are shown in a schematic view in FIG. 4. Likewise, the first current-optimized load modules 6 and the second current-optimized load modules 8 are each physically designed in the same way and are shown in a schematic view in FIG. 5. The left-hand side of each of FIGS. 4 and 5 shows a circuit composed of the corresponding load module 6, 7, 8, 9, the center shows a simplified circuit composed of the corresponding load module 6, 7, 8, 9 shown on the left and the right-hand side shows a symbol used in FIGS. 1 to 3 for the corresponding load module 6, 7, 8, 9 shown on the left and in the center.

As can be seen from FIG. 4, the first dynamics-optimized load modules 7 and the second dynamics-optimized load modules 9 are designed as at least three-stage inverters 12, namely in the present case as seven-stage inverters. The first dynamics-optimized load modules 7 and the second dynamics-optimized load modules 9 thus enable an effective switching frequency or bandwidth of 800 kHz at a maximum current of 75 A. As can also be seen in FIG. 5, the first current-optimized load modules 6 and the second current-optimized load modules 8 are designed as two-stage inverters 11, each of which provides a current of 1000 A.

The arrangement additionally comprises a control device 10 which is in any case configured, with regard to the embodiment shown in FIG. 1, to control the second current-optimized load module 8 based on a low-pass-filtered output voltage of the inverter 1 and to control the second dynamics-optimized load module 9 based on a high-pass-filtered output voltage of the inverter 1. The control device 10 is designed in a manner based on a computer and/or comprises an FPGA.

Since the inverter 1 and also the converter 2 shown in FIG. 3 are of three-phase design, in the refinements shown in FIGS. 1 to 3, the second emulation device 4 comprises a parallel circuit composed of the second current-optimized load module 9 and the second dynamics-optimized load module 8 for each phase. Accordingly, the control device 10 is designed to control the second current-optimized load module 8 of the respective phase based on the low-pass-filtered output voltage of the respective phase of the inverter 1 or, with regard to FIG. 3, the converter 2, and to control the second dynamics-optimized load module 9 of the respective phase based on the high-pass-filtered output voltage of the respective phase of the inverter 1 or, with regard to FIG. 3, the converter 2.

With regard to the refinement shown in FIG. 1, the control device 10 may additionally be configured to control the first current-optimized load module 6 based on an input current of the inverter 1. As also shown in FIG. 2, the first emulation device 3 according to this refinement comprises two parallel circuits composed of a respective first current-optimized load module 6 and the respective first dynamics-optimized load module 7. In this refinement, the control device 10 is configured to control the first current-optimized load module 6 based on a low-pass-filtered input voltage of the inverter 1 and to control the first dynamics-optimized load module 7 based on a high-pass-filtered input voltage of the inverter 1.

As already explained, the refinement shown in FIG. 3 comprises the converter 2. The first emulation device 3 comprises a respective parallel circuit composed of a first dynamics-optimized load module 7 and a first current-optimized load module 6 for each phase.

Accordingly, the control device 10 is designed to control the first current-optimized load module 6 of the respective phase based on the low-pass-filtered input voltage of the respective phase of the converter 2, and to control the first dynamics-optimized load module 7 of the respective phase based on the high-pass-filtered input voltage of the respective phase of the converter 2. The described low-pass filtering operates at a cutoff frequency of ≤5 kHz, in particular ≤3 kHz, and the high-pass filtering operates at the cutoff frequency of ≥8 kHz, in particular ≥10 kHz.

With regard to the specific refinements shown in FIGS. 1 to 3, output voltages U_U__{Mess}, U_V__{Mess}, U_W__{Mess} of the inverter 1 or the converter 2 are measured and supplied to a motor model of the control device 10. Depending on the measured voltages at the inverter 1 or at the converter 2, the motor model calculates motor phase setpoint currents i s u, i s v, i s w, in which a sinusoidal motor current fundamental wave i s u_{fundamental}, i s v_{fundamental}, i s w_{fundamental} (maximum 0 to 5 kHz) is superimposed by a switching-frequency triangular current ripple i s uᵣᵢₚₚₗₑ, i s vᵣᵢₚₚₗₑ, i s wᵣᵢₚₚₗₑ (10 kHz to 100 kHz).

An amplitude of the motor current fundamental wave is set accordingly by a current controller of the inverter 1 or the converter 2 as clocking power electronics. The amplitude of the switching-frequency triangular current ripple results from the motor inductance parametrized in the motor model in conjunction with the input voltage UDC_LINK of the inverter 1 or the converter 2. In order to keep a ripple torque in a tolerable range in traction drives, a drive system is generally designed so that amplitude of the current ripple does not exceed 10% of the amplitude of the current fundamental wave.

In order to significantly increase a power density, a combination of high-current E-load modules optimally dimensioned for the motor current fundamental wave i s u_{fundamental}, i s v_{fundamental}, i s w_{fundamental} (maximum 0 to 5 kHz) and optimized for high current, are limited in terms of bandwidth and are characterized by lower costs, namely the first current-optimized load module 6 and the second current-optimized load module 8, as well as load modules designed for highest dynamics are selected for the switching-frequency triangular current ripple i s uᵣᵢₚₚₗₑ, i s vᵣᵢₚₚₗₑ, i s wᵣᵢₚₚₗₑ (10 kHz to 100 kHz), namely the first dynamics-optimized load module 7 and the second dynamics-optimized load module 9. A significantly simplified hardware structure is used to depict the fundamental current wave, so that significant space and costs can be saved.

The motor current setpoint value i s u, i s v, i s w from the motor model is frequency-selectively filtered and separated into i s u_{fundamental}, i s v_{fundamental}, i s w_{fundamental} (maximum 0 to 5 kHz) and i s uᵣᵢₚₚₗₑ, i s vᵣᵢₚₚₗₑ, i s wᵣᵢₚₚₗₑ (10 kHz to 100 kHz). The simplified high-current E-load modules are assigned the fundamental wave setpoint value i s u_{fundamental}, i s v_{fundamental}, i s w_{fundamental} and the load modules designed for dynamics are assigned the ripple setpoint value i u sᵣᵢₚₚₗₑ, i v sᵣᵢₚₚₗₑ, i w sᵣᵢₚₚₗₑ as setpoint value. The currents iu_{fundamental}, iv_{fundamental}, iw_{fundamental} and iuᵣᵢₚₚₗₑ, iv_{fundamental}, iw_{fundamental} set by the load modules are superimposed by the parallel circuit.

One design example would be as follows:

Notional specification for high-current E-load module, namely for the first current-optimized load module 6 and the second current-optimized load module 8:
I_{RMS_High_Power_Module}=300 A, f_{3db}=8 kHz
Specification for E-load module for high dynamics, namely for the first dynamics-optimized load module 7 and the second dynamics-optimized load module 9:
I_{RMS}=75A, f_{3db}=800 kHz
Motor current emulation system request: Iu, v, w_{RMS_fundamental}=1000 A=>Iu, v, w_{peak_fundamental}=1414 A
Assumption of current ripple to be emulated 10% of Iu, v, w_{peak_fundamental}=1414 A: Iu, v, w_{peak ripple}=0.1*1414 A=141.4 A
In order to cover the motor fundamental wave including current ripple, the following combination could be chosen:
3*high-current E-load module per motor phase, namely the first current-optimized load module 6 and the second current-optimized load module 8
=>Iu, v, w_{RMS_fundamental}=900 A=>Iu, v, w_{Peak_fundamental}=900 A*sqrt(2)=1272.79 A
3*dynamics E-load module, namely for the first dynamics-optimized load module 7 and the second dynamics-optimized load module 9, per motor phase:
=>Iu, v, w_{RMS_ripple}=225A=>Iu, v, w_{Peak_ripple}=225A*sqrt(2)=318.98A
Iu, v, w_{RMS}=Iu, v, w_{RMS_fundamental}+Iu, v, w_{RMS_ripple}=900 A+225 A=1125 A/Iu, v, w_{Peak}=Iu, v, w_{Peak_fundamental}+Iu, v, w_{Peak_ripple}=1272.79 A+318.98 A=1591.77 A

In contrast, consider the prior-art design example:

Motor current emulation system request: Iu, v, w_{RMS_fundamental}=1000 A=>Iu, v, w_{peak_fundamental}=1414 A
N_{modules}=Iu, v, w_{Peak_fundamental}/I_{Peak}=1414 A/(75A*sqrt(2))=13.33
14*E-load module per motor phase are required, which is much more complex.

The exemplary embodiments described are purely examples that can be modified and/or supplemented in a variety of ways within the scope of the claims. Each feature that has been described for a particular exemplary embodiment can be used independently or in combination with other features in any other desired exemplary embodiment. Any feature that has been described for an exemplary embodiment of a particular category can also be used in a corresponding manner in an exemplary embodiment of another category.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

Inverter 1
Converter 2
First emulation device 3
Second emulation device 4
DC link capacitor 5
First current-optimized load module 6
First dynamics-optimized load module 7
Second current-optimized load module 8
Second dynamics-optimized load module 9
Control device 10
At least two-stage inverter 11
At least three-stage inverter 12

1. A system for testing an inverter and/or a converter, comprising:
a first emulation device configured to emulate a power generator;
a second emulation device configured to emulate a power consumer; and
a control device;
wherein the inverter and/or the converter is connected between the first emulation device and the second emulation device and has a direct current (DC) link capacitor connected in parallel;
wherein the first emulation device comprises at least one first current-optimized load module;
wherein the second emulation device comprises at least one parallel circuit composed of a second dynamics-optimized load module and a second current-optimized load module;
wherein the first current-optimized load module and the second current-optimized load module each comprise an at least two-stage inverter;
wherein the second dynamics-optimized load module comprises an at least three-stage inverter; and
wherein the control device is configured to:
control the second current-optimized load module based on a low-pass-filtered output voltage of the inverter and/or the converter; and
control the second dynamics-optimized load module based on a high-pass-filtered output voltage of the inverter and/or the converter.

2. The system according to claim 1, wherein the inverter and/or the converter are of three-phase design;
wherein the second emulation device comprises a respective parallel circuit composed of the second dynamics-optimized load module and the second current-optimized load module for each phase; and
wherein the control device is configured to:
control the second current-optimized load module of the respective phase based on the low-pass-filtered output voltage of the respective phase of the inverter and/or the converter; and
control the second dynamics-optimized load module of the respective phase based on the high-pass-filtered output voltage of the respective phase of the inverter and/or the converter.

3. The system according to claim 1, wherein the system comprises the inverter; and
wherein the control device is configured to control the first current-optimized load module based on an input current of the inverter.

4. The system according to claim 3, wherein the first emulation device comprises at least one parallel circuit composed of a first current-optimized load module and the first dynamics-optimized load module; and
wherein the control device is configured to:
control the first current-optimized load module based on a low-pass-filtered input current of the inverter; and
control the first dynamics-optimized load module based on a high-pass-filtered input current of the inverter.

5. The system according to claim 3, wherein the first emulation device comprises at least two parallel circuits composed of a respective first current-optimized load module and a respective first dynamics-optimized load module; and
wherein the control device is configured to:
control the respective first current-optimized load modules based on a low-pass-filtered input current of the inverter; and
control the respective first dynamics-optimized load modules based on a high-pass-filtered input current of the inverter.

6. The system according to claim 1, wherein the system comprises the converter;
wherein the converter is of three-phase design;
wherein the first emulation device comprises a respective parallel circuit composed of a first dynamics-optimized load module and the first current-optimized load module for each phase; and
wherein the control device is configured to:
control the first current-optimized load module of the respective phase based on the low-pass-filtered input voltage of the respective phase of the converter; and
control the first dynamics-optimized load module of the respective phase based on the high-pass-filtered input voltage of the respective phase of the converter.

7. The system according to claim 1, wherein the low-pass filtering is carried out at a cutoff frequency of ≤5 kHz, and the high-pass filtering is carried out at a cutoff frequency of ≥8 kHz.

8. The system according to claim 1, wherein the low-pass filtering is carried out at a cutoff frequency of ≤3 kHz, and the high-pass filtering is carried out at a cutoff frequency of ≥10 kHz.

9. The system according to claim 1, wherein the system comprises:
a plurality of first current-optimized load modules connected in series; and/or
a plurality of second current-optimized load modules connected in series.

10. The system according to claim 1, wherein the control device comprises a field-programmable gate array (FPGA).

11. The system according to claim 1, wherein the first dynamics-optimized load module and the second dynamics-optimized load module each comprise an at least seven-stage inverter.

12. The system according to claim 1, wherein the first emulation device comprises a battery and/or a generator; and/or
wherein the second emulation device comprises a motor and/or a power supply system.

13. The system according to claim 1, wherein the inverter and/or the converter is an inverter and/or a converter of a wind power plant, a power supply system, and/or a battery.

14. A method for testing an inverter and/or a converter, comprising:
controlling, by a control device of a system, a second current-optimized load module of the system based on a low-pass-filtered output voltage of the inverter and/or the converter, and
controlling, by the control device, a second dynamics-optimized load module of the system based on a high-pass-filtered output voltage of the inverter and/or the converter;
wherein the system comprises a first emulation device configured to emulate an energy generator, a second emulation device configured to emulate an energy consumer, and the control device;
wherein the inverter and/or converter is connected between the first emulation device and the second emulation device and has a direct current (DC) link capacitor connected in parallel;
wherein the first emulation device comprises at least one first current-optimized load module;
wherein the second emulation device comprises at least one parallel circuit composed of the second dynamics-optimized load module and the second current-optimized load module;
wherein the first current-optimized load module and the second current-optimized load module each comprise an at least two-stage inverter; and
wherein the second dynamics-optimized load module comprises an at least three-stage inverter.
